(19) United States
(12) Patent Application Publication
(10) Pub. No.: US 2025/0289222 A1
(43) Pub. Date: Sep. 18, 2025

(54) Liquid Discharge Head, Liquid Discharge Device, And Method Of Manufacturing Liquid Discharge Head

(71) Applicant: SEIKO EPSON CORPORATION, Tokyo (JP)

(72) Inventors: Motoki TAKABE, Shiojiri (JP); Toshihiro SHIMIZU, Fujimi (JP); Masao NAKAYAMA, Shiojiri (JP)

(21) Appl. No.: 19/076,186

(22) Filed: Mar. 11, 2025

(30) Foreign Application Priority Data
Mar. 12, 2024 (JP) 2024-037715

(51) Int. Cl. B41J 2/14; H10N 30/02; H10N 30/063; H10N 30/853; H10N 30/88

(52) U.S. Cl. CPC B41J 2/14233; H10N 30/02; H10N 30/063; H10N 30/8554; H10N 30/88; B41J 2002/14241; B41J 2202/03; B41J 2202/22

(57) ABSTRACT

a protective layer provided on the other side with respect to the piezoelectric body in a boundary region, which is a boundary between a first region and a second region, in the extending direction when the first region is set to a region where the piezoelectric body overlaps the second electrode in the lamination direction, and the second region is set to a region where the piezoelectric body is present and the second electrode is not present in the lamination direction, in which the protective layer is made of the same material as the piezoelectric body.

The present application is based on, and claims priority from JP Application Serial Number 2024-037715, filed Mar. 12, 2024, the disclosure of which is hereby incorporated by reference herein in its entirety.

### BACKGROUND

### 1. Technical Field

The present disclosure relates to a liquid discharge head, a liquid discharge device, and a method of manufacturing the liquid discharge head.

### 2. Related Art

JP-A-2016-135611 discloses a liquid ejecting head having a protective film covering a region including a boundary between a region where a piezoelectric layer is not covered with an upper electrode and a region where the piezoelectric layer is covered with the upper electrode.

Generally, when forming an electrode that covers a part of a piezoelectric body, an electrode that covers the entire piezoelectric body is first formed, and then a part of the electrode is removed by etching. At this time, a crack may be generated in the piezoelectric body in the vicinity of the end portion of the electrode that remains without being removed. When moisture is mixed in the crack, there is a problem in that two electrodes formed to interpose the piezoelectric body are short-circuited and the burning occurs in the piezoelectric body. Therefore, a technique is desired for reducing the possibility that the burning occurs in the piezoelectric body in the vicinity of the end portion of the electrode that covers a part of the piezoelectric body.

### SUMMARY

According to a first aspect of the present disclosure, there is provided a liquid discharge head. The liquid discharge head includes a piezoelectric body, a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven, a first electrode provided on one side of a lamination direction, which is a direction intersecting the extending direction and the arrangement direction, with respect to the piezoelectric body, a second electrode provided on another side of the lamination direction, which is a side opposite to the one side, with respect to the piezoelectric body, and a protective layer provided on the other side with respect to the piezoelectric body in a boundary region, which is a boundary between a first region and a second region, in the extending direction when the first region is set to a region where the piezoelectric body overlaps the second electrode in the lamination direction, and the second region is set to a region where the piezoelectric body is present and the second electrode is not present in the lamination direction, in which the protective layer is made of the same material as the piezoelectric body.

According to a second aspect of the present disclosure, there is provided a liquid discharge device. The liquid discharge device includes the liquid discharge head according to the first aspect, and a control section that controls a discharge operation of discharging a liquid from the liquid discharge head.

According to a third aspect of the present disclosure, there is provided a method of manufacturing a liquid discharge head. The method of manufacturing a liquid discharge head, the liquid discharge head including a piezoelectric body and a first electrode provided on one side of a lamination direction with respect to the piezoelectric body, the method includes a first step of forming a second electrode on another side of the lamination direction, which is a side opposite to the one side, with respect to the piezoelectric body; a second step of removing the second electrode in a second region by etching such that an end portion of the second electrode in an extending direction, which is a direction intersecting the lamination direction, is located at a boundary region when a region where the piezoelectric body overlaps the second electrode in the lamination direction is set to a first region, a region where the piezoelectric body is present and the second electrode is not present in the lamination direction is set to the second region, and a region which is a boundary between the first region and the second region in the extending direction is set to the boundary region; a third step of forming a protective layer made of the same material as the piezoelectric body on the other side of the piezoelectric body and the second electrode; and a fourth step of removing the protective layer in the first region and the second region by etching.

### BRIEF DESCRIPTION OF THE DRAWINGS

FIG. 1 is an explanatory diagram illustrating a schematic configuration of a liquid discharge device according to a first embodiment.

FIG. 2 is an exploded perspective view illustrating a configuration of a liquid discharge head.

FIG. 3 is an explanatory diagram illustrating the configuration of the liquid discharge head in a plan view.

FIG. 4 is a cross-sectional view illustrating a position IV-IV in FIG. 3.

FIG. 5 is a cross-sectional view schematically illustrating a detailed configuration of a piezoelectric element.

FIG. 6 is a flowchart illustrating a method of manufacturing a liquid discharge head.

FIG. 7 is a view illustrating a state in which a first layer of a second electrode is formed on the −Z direction side of the piezoelectric body.

FIG. 8 is a view illustrating a state in which the first layer is etched.

FIG. 9 is a view illustrating a state in which a protective layer is formed on a −Z direction side of a piezoelectric body and a first layer.

FIG. 10 is a view illustrating a state in which the protective layer of a first region and a second region is removed.

FIG. 11 is a view illustrating a state in which a second layer is formed on the −Z direction side of the piezoelectric body, the first layer, and the protective layer.

FIG. 12 is a view illustrating a state in which the second layer is etched.

### DESCRIPTION OF EMBODIMENTS

### A. First Embodiment

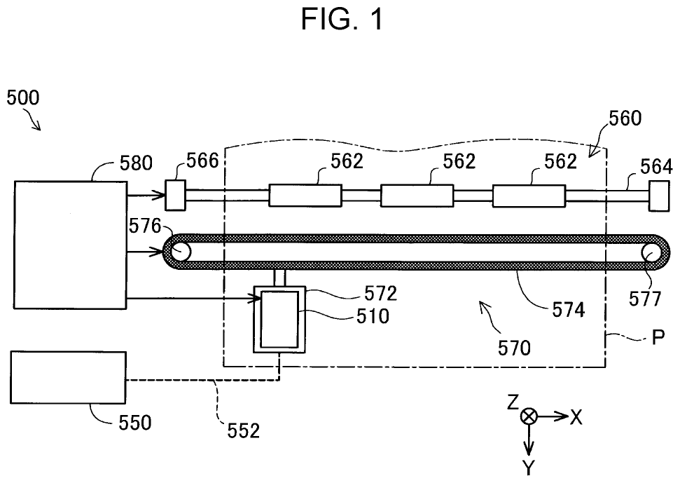

FIG. 1 is an explanatory diagram illustrating a schematic configuration of a liquid discharge device 500 according to a first embodiment. In the present embodiment, the liquid discharge device 500 is an ink jet printer that discharges ink as an example of a liquid onto printing paper P to form an image. The liquid discharge device 500 may use any kind of medium, such as a resin film or a cloth, as a target on which ink is to be discharged, instead of the printing paper P. X, Y, and Z illustrated in FIG. 1 and each drawing subsequent to FIG. 1 represent three spatial axes orthogonal to each other. In the present specification, directions along the axes are also referred to as an X-axis direction, a Y-axis direction, and a Z-axis direction. In specifying the direction, a positive direction is “+” and a negative direction is “−” so that positive and negative signs are used together in the direction notation, and description will be performed while a direction to which an arrow faces in each drawing is the +direction and an opposite direction thereof is the −direction. In the present embodiment, the Z-axis direction coincides with a vertical direction, the +Z direction indicates vertically downward, and the −Z direction indicates vertically upward. Further, when the positive direction and the negative direction are not limited, the three X, Y, and Z will be described as the X axis, the Y axis, and the Z axis.

The liquid discharge device 500 includes a liquid discharge head 510, an ink tank 550, a transport mechanism 560, a movement mechanism 570, and a control section 580. The liquid discharge head 510 is formed with a plurality of nozzles, discharges inks of a total of four colors, for example, black, cyan, magenta, and yellow in the +Z direction to form an image on a printing paper P. The liquid discharge head 510 is mounted on the carriage 572 and reciprocates in a main scanning direction with the movement of the carriage 572. In the present embodiment, the main scanning directions are the +X direction and the −X direction. The liquid discharge head 510 may further discharge ink of a random color such as light cyan, light magenta, or clear white, in addition to the four colors.

The ink tank 550 accommodates the ink to be discharged to the liquid discharge head 510. The ink tank 550 is coupled to the liquid discharge head 510 by a resin tube 552. The ink in the ink tank 550 is supplied to the liquid discharge head 510 via the tube 552. Instead of the ink tank 550, a bag-shaped liquid pack formed of a flexible film may be provided.

The transport mechanism 560 transports the printing paper P in a sub-scanning direction. The sub-scanning direction is a direction that intersects the X-axis direction, which is a main scanning direction, and is the +Y direction and the −Y direction in the present embodiment. The transport mechanism 560 includes a transport rod 564, on which three transport rollers 562 are mounted, and a transport motor 566 for rotatably driving the transport rod 564. When the transport motor 566 rotatably drives the transport rod 564, the printing paper P is transported in the +Y direction, which is the sub-scanning direction. The number of the transport rollers 562 is not limited to three and may be a random number. Further, a configuration, in which a plurality of transport mechanisms 560 are provided, may be provided.

The movement mechanism 570 includes a carriage 572, a transport belt 574, a movement motor 576, and a pulley 577. The carriage 572 mounts the liquid discharge head 510 in a state in which the ink can be discharged. The carriage 572 is fixed to the transport belt 574. The transport belt 574 is bridged between the movement motor 576 and the pulley 577. When the movement motor 576 is rotatably driven, the transport belt 574 reciprocates in the main scanning direction. As a result, the carriage 572 fixed to the transport belt 574 also reciprocates in the main scanning direction.

The control section 580 is configured as a microcomputer including a CPU and a storage section. The storage section is, for example, a non-volatile memory such as an EEPROM that can be erased by an electric signal, a non-volatile memory such as a One-Time-PROM and an EPROM that can be erased by ultraviolet rays, or a non-volatile memory such as a PROM that cannot be erased. The storage section stores various programs for realizing functions provided in the present embodiment. The CPU oversees the control of each section of the liquid discharge device 500 by developing and executing a program stored in the storage section. The control section 580 controls the reciprocating operation of the carriage 572 along the main scanning direction, the transport operation of the printing paper P along the sub-scanning direction, and the discharge operation of discharging the liquid from the liquid discharge head 510.

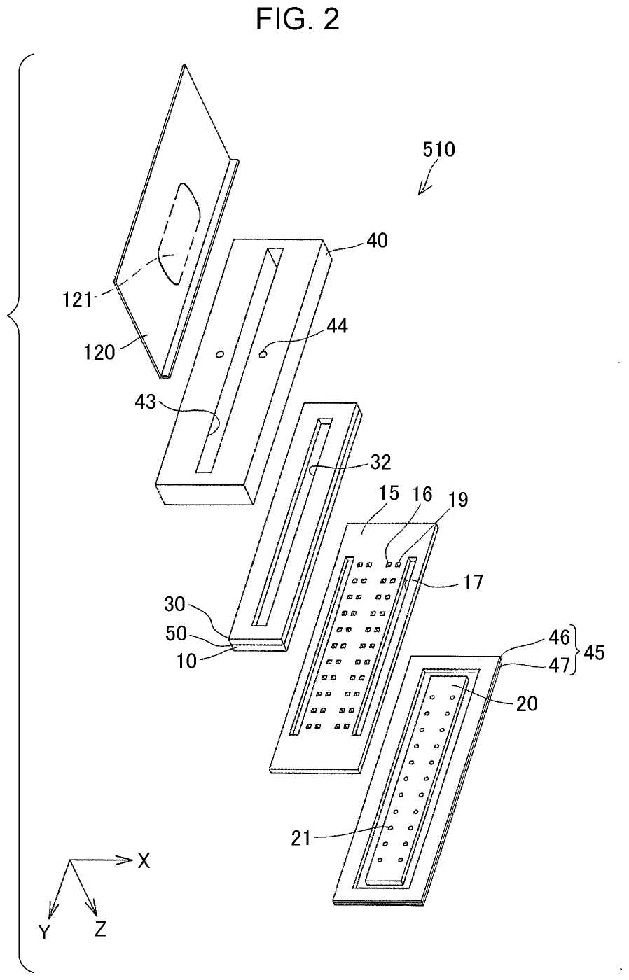

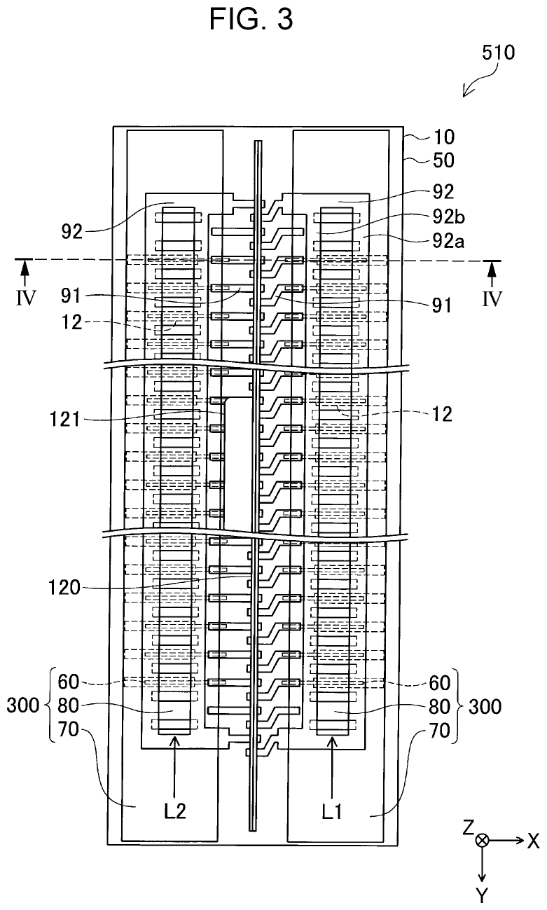

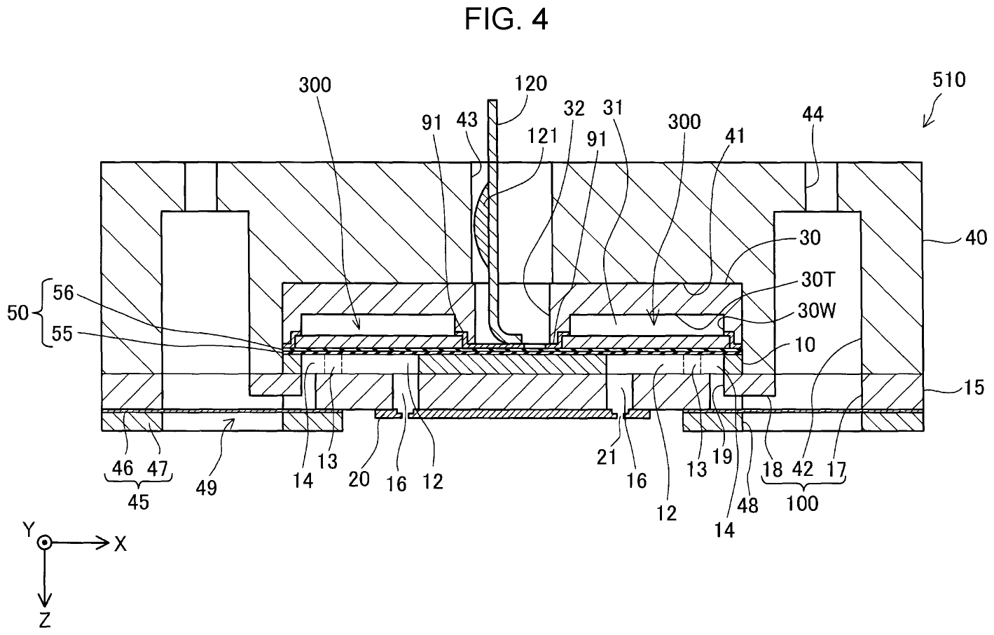

A detailed configuration of the liquid discharge head 510 will be described with reference to FIGS. 2 to 4. FIG. 2 is an exploded perspective view illustrating the configuration of the liquid discharge head 510. FIG. 3 is an explanatory diagram illustrating the configuration of the liquid discharge head 510 in a plan view. In the present disclosure, the “plan view” means a state in which an object is viewed along a lamination direction to be described later. FIG. 3 illustrates the configuration around a pressure chamber substrate 10 and a vibration plate 50 in the liquid discharge head 510. In order to facilitate understanding of the technique, a protective layer 83, a sealing substrate 30, a case member 40, and the like are not illustrated. FIG. 4 is a cross-sectional view illustrating an IV-IV position of FIG. 3.

The liquid discharge head 510 includes a pressure chamber substrate 10, a communication plate 15, a nozzle plate 20, a compliance substrate 45, a vibration plate 50, a sealing substrate 30, a case member 40, a wiring substrate 120, which are illustrated in FIG. 2, and a piezoelectric element 300 illustrated in FIG. 3. The liquid discharge head 510 is configured by laminating these laminated members. In the present disclosure, a direction in which the laminated members forming the liquid discharge head 510 are laminated is also referred to as a “lamination direction”. In the present embodiment, the lamination direction coincides with the Z-axis direction. In the present disclosure, the +Z direction side with respect to a predetermined reference position is also referred to as “one side of the lamination direction” or “lower side”, and the −Z direction side with respect to a predetermined reference position is also referred to as “the other side of the lamination direction” or “upper side”.

The pressure chamber substrate 10 is formed by using, for example, a silicon substrate, a glass substrate, an SOI substrate, various ceramic substrates, and the like. As illustrated in FIG. 3, a plurality of pressure chambers 12 are provided on the pressure chamber substrate 10. An ink flow path provided on the pressure chamber substrate 10, such as the pressure chamber 12, is formed by performing anisotropic etching on the pressure chamber substrate 10 from the surface on the +Z direction side. The pressure chamber 12 is provided to extend along the X-axis direction. Specifically, the pressure chamber 12 is formed in a substantially rectangular shape in which the length in the X-axis direction is longer than the length in the Y-axis direction in a plan view. The shape of the pressure chamber 12 is not limited to the rectangular shape, and may be a parallelogram shape, a polygonal shape, an oval shape, or the like. The oval shape means a shape in which both end portions in a longitudinal direction are semicircular based on a rectangular shape, and includes a rounded rectangular shape, an elliptical shape, an egg shape, and the like. In the present disclosure, the X-axis direction is also referred to as an “extending direction”.

As illustrated in FIG. 3, the plurality of pressure chambers 12 are arranged along a direction intersecting the extending direction on the pressure chamber substrate 10. In plan view of the liquid discharge head 510 along the lamination direction, a direction in which the plurality of pressure chambers 12 are arranged is also referred to as an “arrangement direction”. That is, the arrangement direction is a direction intersecting the extending direction and the lamination direction. In the present embodiment, the plurality of pressure chambers 12 are arranged in two rows parallel to each other with the Y-axis direction as the arrangement direction. In the example of FIG. 3, the pressure chamber substrate 10 is provided with two pressure chamber rows, that is, a first pressure chamber row L1 having a first arrangement direction parallel to the Y-axis direction and a second pressure chamber row L2 having a second arrangement direction parallel to the Y-axis direction. The first pressure chamber row L1 and the second pressure chamber row L2 are disposed on both sides with the wiring substrate 120 interposed therebetween. Specifically, the second pressure chamber row L2 is disposed on the opposite side of the first pressure chamber row L1 with the wiring substrate 120 interposed therebetween in the X-axis direction, which is the extending direction. In the example of FIG. 3, the second pressure chamber row L2 is disposed in the −X direction with the wiring substrate 120 interposed between the second pressure chamber row L2 and the first pressure chamber row L1. In the plurality of pressure chambers 12, all the pressure chambers 12 do not necessarily have to be arranged in a straight line. For example, the plurality of pressure chambers 12 may be arranged along the Y-axis direction according to so-called staggered arrangement in which every other pressure chamber 12 is alternately disposed in the intersection direction.

As illustrated in FIG. 2, the communication plate 15, the nozzle plate 20, and the compliance substrate 45 are laminated on the +Z direction side of the pressure chamber substrate 10. The communication plate 15 is, for example, a flat plate member using a silicon substrate, a glass substrate, an SOI substrate, various ceramic substrates, a metal substrate, or the like. Examples of the metal substrate include a stainless steel substrate or the like. The communication plate 15 is provided with a nozzle communication path 16, a first manifold portion 17, a second manifold portion 18 illustrated in FIG. 4, and a supply communication path 19. It is preferable that the communication plate 15 is formed by using a material having a thermal expansion coefficient substantially the same as a thermal expansion coefficient of the pressure chamber substrate 10. As a result, when the temperatures of the pressure chamber substrate 10 and the communication plate 15 change, the warping of the pressure chamber substrate 10 and the communication plate 15 due to a difference in the thermal expansion coefficient can be suppressed.

As illustrated in FIG. 4, the nozzle communication path 16 is a flow path that communicates the pressure chamber 12 and a nozzle 21. The first manifold portion 17 and the second manifold portion 18 function as a part of a manifold 100 which is a common liquid chamber in which a plurality of pressure chambers 12 communicate with each other. The first manifold portion 17 is provided to penetrate the communication plate 15 in the Z-axis direction. Further, as illustrated in FIG. 4, the second manifold portion 18 is provided on a surface of the communication plate 15 on the +Z direction side without penetrating the communication plate 15 in the Z-axis direction.

As illustrated in FIG. 4, the supply communication path 19 is a flow path coupled to a pressure chamber supply path 14 provided on the pressure chamber substrate 10. The pressure chamber supply path 14 is a flow path coupled to one end portion of the pressure chamber 12 in the X-axis direction via a throttle portion 13. The throttle portion 13 is a flow path provided between the pressure chamber 12 and the pressure chamber supply path 14. The throttle portion 13 is a flow path in which an inner wall protrudes from the pressure chamber 12 and the pressure chamber supply path 14 and which is formed narrower than the pressure chamber 12 and the pressure chamber supply path 14. Thereby, the throttle portion 13 is set such that the flow path resistance is higher than those of the pressure chamber 12 and the pressure chamber supply path 14. With the configuration, even when pressure is applied to the pressure chamber 12 by the piezoelectric element 300 when the ink is discharged, the ink in the pressure chamber 12 can be suppressed or prevented from flowing back to the pressure chamber supply path 14. A plurality of supply communication paths 19 are arranged along the Y-axis direction, that is, the arrangement direction, and are individually provided for the respective pressure chambers 12. The supply communication path 19 and the pressure chamber supply path 14 communicates the second manifold portion 18 with each pressure chamber 12, and supplies the ink in the manifold 100 to each pressure chamber 12.

The nozzle plate 20 is provided on a side opposite to the pressure chamber substrate 10, that is, on a surface of the communication plate 15 on the +Z direction side with the communication plate 15 interposed therebetween. The material of the nozzle plate 20 is not particularly limited, and, for example, a silicon substrate, a glass substrate, an SOI substrate, various ceramic substrates, and a metal substrate can be used. Examples of the metal substrate include a stainless steel substrate or the like. As the material of the nozzle plate 20, an organic material, such as a polyimide resin, can also be used. However, it is preferable that the nozzle plate 20 uses a material substantially the same as the thermal expansion coefficient of the communication plate 15. As a result, when the temperatures of the nozzle plate 20 and the communication plate 15 change, the warping of the nozzle plate 20 and the communication plate 15 due to the difference in the thermal expansion coefficient can be suppressed.

A plurality of nozzles 21 are formed on the nozzle plate 20. Each nozzle 21 communicates with each pressure chamber 12 via the nozzle communication path 16. As illustrated in FIG. 2, the plurality of nozzles 21 are arranged along the arrangement direction of the pressure chamber 12, that is, the Y-axis direction. The nozzle plate 20 is provided with two nozzle rows in which the plurality of nozzles 21 are arranged in a row. The two nozzle rows respectively correspond to the first pressure chamber row L1 and the second pressure chamber row L2.

As illustrated in FIG. 4, the compliance substrate 45 is provided together with the nozzle plate 20 on the side opposite to the pressure chamber substrate 10 with the communication plate 15 interposed therebetween, that is, on a surface of the communication plate 15 on the +Z direction side. The compliance substrate 45 is provided around the nozzle plate 20 and covers openings of the first manifold portion 17 and the second manifold portion 18 provided in the communication plate 15. The compliance substrate 45 includes, for example, a sealing film 46 made of a flexible thin film and a fixed substrate 47 made of a hard material such as a metal. As illustrated in FIG. 4, a region of the fixed substrate 47 facing the manifold 100 is completely removed in a thickness direction, and thus an opening portion 48 is defined. Therefore, one surface of the manifold 100 is a compliance portion 49 sealed only by the sealing film 46.

As illustrated in FIG. 4, the vibration plate 50 and the piezoelectric element 300 are laminated on a side opposite to the communication plate 15 or the like, that is, on a surface of the pressure chamber substrate 10 on the −Z direction side with the pressure chamber substrate 10 interposed therebetween. The piezoelectric element 300 bends and deforms the vibration plate 50 to cause a pressure change in the ink in the pressure chamber 12. In FIG. 4, illustration of the piezoelectric element 300 is simplified.

The vibration plate 50 is provided between the piezoelectric element 300 and the pressure chamber substrate 10. The vibration plate 50 is provided at a position closer to the pressure chamber substrate 10 side than the piezoelectric element 300, and includes an elastic film 55 containing silicon oxide (SiO₂) and an insulator film 56 that is provided on the elastic film 55 and contains a zirconium oxide film (ZrO₂). The elastic film 55 constitutes a surface of the flow path, such as the pressure chamber 12, on the −Z direction side. In addition, the vibration plate 50 may be composed of, for example, either the elastic film 55 or the insulator film 56, and may further include another film other than the elastic film 55 and the insulator film 56. Examples of the material of the other film include silicon, silicon nitride, and the like.

As illustrated in FIG. 2, the sealing substrate 30 having substantially the same size as the pressure chamber substrate 10 in a plan view is further bonded to the surface of the pressure chamber substrate 10 on the −Z direction side by an adhesive or the like. As illustrated in FIG. 4, the sealing substrate 30 includes a ceiling portion 30T, a wall portion 30W, a holding portion 31, and a through hole 32. The holding portion 31 is a space defined by the ceiling portion 30T and the wall portion 30W, and protects an active portion of the piezoelectric element 300 by accommodating the piezoelectric element 300. In the present embodiment, the holding portions 31 are provided for each row of the piezoelectric elements 300. More specifically, two holding portions 31 corresponding to the first pressure chamber row L1 and the second pressure chamber row L2 are formed to be adjacent to each other. The through hole 32 penetrates the sealing substrate 30 along the Z-axis direction. The through hole 32 is disposed between the two holding portions 31 in plan view, and is formed in a long rectangular shape along the Y-axis direction.

As illustrated in FIG. 4, the case member 40 is fixed on the sealing substrate 30. The case member 40 forms the manifold 100 that communicates with the plurality of pressure chambers 12, together with the communication plate 15. The case member 40 has substantially the same outer shape as the communication plate 15 in plan view, and is bonded to cover the sealing substrate 30 and the communication plate 15.

The case member 40 has an accommodation section 41, a supply port 44, a third manifold portion 42, and a coupling port 43. The accommodation section 41 is a space having a depth in which the pressure chamber substrate 10, the vibration plate 50, and the sealing substrate 30 can be accommodated. The third manifold portion 42 is a space provided in the vicinity of both ends of the accommodation section 41 in the X-axis direction in the case member 40. The manifold 100 is formed by coupling the third manifold portion 42 to the first manifold portion 17 and the second manifold portion 18 provided in the communication plate 15. The manifold 100 has a long shape in the Y-axis direction. The supply port 44 communicates with the manifold 100 to supply ink to each manifold 100. The coupling port 43 is a through hole that communicates with the through hole 32 of the sealing substrate 30, and the wiring substrate 120 is inserted thereto.

In the liquid discharge head 510, the ink supplied from the ink tank 550 illustrated in FIG. 1 is taken from the supply port 44 illustrated in FIG. 4, and an internal flow path from the manifold 100 to the nozzle 21 is filled with ink. Thereafter, a voltage based on the drive signal is applied to each of the piezoelectric elements 300 corresponding to the plurality of pressure chambers 12. Thereby, the vibration plate 50 bends and deforms together with the piezoelectric element 300, and thus the volume of each pressure chamber 12 changes and the internal pressure increases. Therefore, ink droplets are discharged from each nozzle 21.

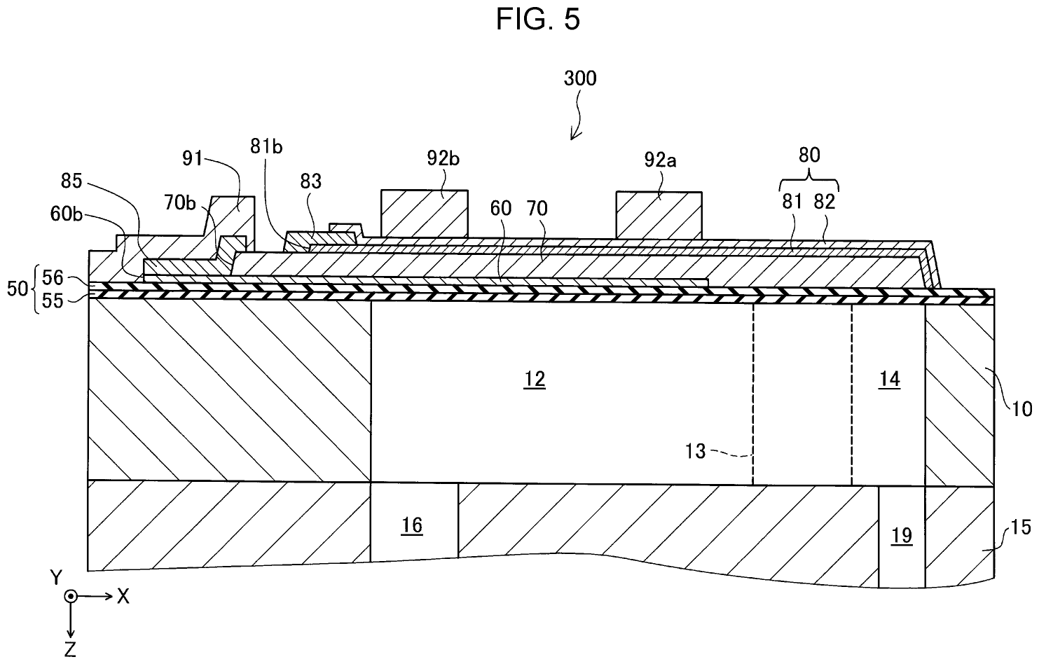

The configuration of the piezoelectric element 300 will be described with reference to FIGS. 3 and 4 and FIG. 5 as appropriate. FIG. 5 is a cross-sectional view schematically illustrating the detailed configuration of the piezoelectric element 300.

As illustrated in FIG. 5, the piezoelectric element 300 has a first electrode 60, a piezoelectric body 70, and a second electrode 80. The first electrode 60, the piezoelectric body 70, and the second electrode 80 are laminated in this order in the −Z direction of the lamination direction. The piezoelectric body 70 is provided between the first electrode 60 and the second electrode 80 in the lamination direction. The first electrode 60 is provided on the +Z direction side of the piezoelectric body 70, and the second electrode 80 is provided on the −Z direction side of the piezoelectric body 70.

The first electrode 60 and the second electrode 80 are electrically coupled to the wiring substrate 120 illustrated in FIGS. 3 and 4 via the drive wiring. The drive wiring includes a first drive wiring 91 that electrically couples the wiring substrate 120 and the first electrode 60, and a second drive wiring 92 that electrically couples the wiring substrate 120 and the second electrode 80. The first electrode 60 and the second electrode 80 apply a voltage corresponding to the drive signal to the piezoelectric body 70. The drive voltage is a voltage applied to the piezoelectric element 300 from the first electrode 60 and the second electrode 80 in order to drive the piezoelectric element 300 by the control section 580. In the piezoelectric element 300, when a voltage is applied between the first electrode 60 and the second electrode 80, a portion where the piezoelectric distortion occurs in the piezoelectric body 70 is also referred to as an active portion, and a portion where the piezoelectric distortion does not occur in the piezoelectric body 70 is also referred to as a non-active portion.

A different drive voltage is applied to the first electrode 60 according to a discharge amount of ink, and a predetermined reference voltage is applied to the second electrode 80 regardless of the discharge amount of ink. When a voltage difference is generated between the first electrode 60 and the second electrode 80 by applying the drive voltage and the reference voltage, the piezoelectric body 70 of the piezoelectric element 300 is deformed. Due to the deformation of the piezoelectric body 70, the vibration plate 50 is deformed or vibrated, so that the volume of the pressure chamber 12 changes. Due to the change in the volume of the pressure chamber 12, pressure is applied to the ink accommodated in the pressure chamber 12, and the ink is discharged from the nozzle 21 via the nozzle communication path 16.

In the present embodiment, the first electrode 60 is an individual electrode individually provided for the plurality of pressure chambers 12. As illustrated in FIG. 5, the first electrode 60 is a lower electrode provided on the opposite side to the second electrode 80 with the piezoelectric body 70 interposed therebetween, that is, on the lower side of the piezoelectric body 70. The thickness of the first electrode 60 is formed to be, for example, approximately 80 nanometers. For example, the first electrode 60 is formed of a conductive material including a metal, such as platinum (Pt), iridium (Ir), gold (Au), titanium (Ti), and a conductive metal oxide such as indium tin oxide abbreviated as ITO. The first electrode 60 may be formed by laminating a plurality of materials such as platinum (Pt), iridium (Ir), gold (Au), and titanium (Ti). In the present embodiment, platinum (Pt) is used as the first electrode 60.

As illustrated in FIG. 3, the piezoelectric body 70 has a predetermined width in the X-axis direction, and has a long rectangular shape along the arrangement direction of the pressure chambers 12, that is, the Y-axis direction. The thickness of the piezoelectric body 70 is formed, for example, from approximately 1000 nanometers to 4000 nanometers. Examples of the piezoelectric body 70 include a crystal film having a perovskite structure formed on the first electrode 60 and made of a ferroelectric ceramic material exhibiting an electromechanical conversion action, that is, a so-called perovskite type crystal. As the material of the piezoelectric body 70, for example, a ferroelectric piezoelectric material such as lead zirconate titanate (PZT) or a material to which a metal oxide, such as niobium oxide, nickel oxide, or magnesium oxide, is added can be used. Specifically, lead titanate (PbTiO₃), lead zirconate titanate (Pb(Zr,Ti)O₃), lead zirconate (PbZrO₃), lead lanthanum titanate ((Pb,La),TiO₃), lead lanthanum zirconate titanate ((Pb,La)(Zr,Ti)O₃), lead magnesium niobate zirconium titanate (Pb(Zr,Ti)(Mg,Nb)O₃), or the like may be used. In the present embodiment, a material containing lead zirconate titanate (PZT) was used as the piezoelectric body 70.

The material of the piezoelectric body 70 is not limited to the lead-based piezoelectric material containing lead, and a lead-free piezoelectric material containing no lead can also be used. Examples of the lead-free piezoelectric material include bismuth iron acid ((BiFeO₃), abbreviated as “BFO”), barium titanate ((BaTiO₃), abbreviated to “BT”), potassium sodium niobate ((K,Na)(NbO₃), abbreviated to “KNN”), potassium sodium lithium niobate ((K,Na,Li)(NbO₃)), potassium sodium lithium tantalate niobate ((K,Na,Li)(Nb, Ta)O₃), bismuth potassium titanate ((Bi_{1/2}K_{1/2}) TiO₃, abbreviated to “BKT”), bismuth sodium titanate ((Bi_{1/2}Na_{1/2}) TiO₃, abbreviated to “BNT”), bismuth manganate (BiMnO₃, abbreviated to “BM”), a composite oxide containing bismuth, potassium, titanium, and iron and having a perovskite structure (x[(BiₓK₁₋ₓ)TiO₃]-(1-x) [BiFeO₃], abbreviated to “BKT-BF”), a composite oxide containing bismuth, iron, barium, and titanium and having a perovskite structure ((1-x)[BiFeO₃]-x[BaTiO₃], abbreviated to “BFO-BT”), and a material ((1-x)[Bi(Fe_{1-y}M_{y})O₃]-x[BaTiO₃], M being Mn, Co, or Cr), which is obtained by adding metals such as manganese, cobalt, and chromium to the composite oxide.

As illustrated in FIG. 3, the second electrode 80 is a common electrode that is commonly provided for the plurality of pressure chambers 12. The second electrode 80 has a predetermined width in the X-axis direction, and is provided to extend along the arrangement direction of the pressure chambers 12, that is, the Y-axis direction. As illustrated in FIG. 5, the second electrode 80 is an upper electrode provided on the opposite side to the first electrode 60 with the piezoelectric body 70 interposed therebetween, that is, on the upper side of the piezoelectric body 70. The second electrode 80 has a first layer 81 and a second layer 82 provided on the −Z direction side of the first layer 81. The first layer 81 and the second layer 82 are made of the same material. As the materials of the first layer 81 and the second layer 82, similarly to the first electrode 60, for example, a metal such as platinum (Pt), iridium (Ir), gold (Au), and titanium (Ti), or a conductive material including conductive metal oxide such as indium tin oxide abbreviated as ITO is used. The first layer 81 and the second layer 82 may be formed by laminating a plurality of materials such as platinum (Pt), iridium (Ir), gold (Au), and titanium (Ti). In addition, the first layer 81 and the second layer 82 may be made of different materials. In the present embodiment, iridium (Ir) is used as the second electrode 80.

As illustrated in FIG. 5, a protective layer 83 is formed at an end portion of the second electrode 80 on the −X direction side. At least a part of the protective layer 83 is formed to be interposed between the first layer 81 and the second layer 82 in the lamination direction. The protective layer 83 is a perovskite type crystal made of the same material as the piezoelectric body 70. In the present embodiment, the protective layer 83 contains lead zirconate titanate (PZT). The material of the protective layer 83 is not limited to lead zirconate titanate (PZT), and for example, it is possible to use a material obtained by adding a metal oxide such as niobium oxide, nickel oxide, or magnesium oxide to lead zirconate titanate (PZT). Specifically, lead titanate (PbTiO₃), lead zirconate titanate (Pb(Zr,Ti)O₃), lead zirconate (PbZrO₃), lead lanthanum titanate ((Pb,La), TiO₃), lead lanthanum zirconate titanate ((Pb,La)(Zr,Ti)O₃) or lead magnesium niobate zirconium titanate (Pb(Zr,Ti)(Mg,Nb)O₃), or the like, can be used.

The protective layer 83 is formed such that the (100) orientation degree thereof is lower than the (100) orientation degree of the piezoelectric body 70. The (100) orientation degree is a ratio of the peak intensity from the (100) plane to the sum of the peak intensities from each crystal plane which is acquired by the X-ray diffraction method. The (100) orientation degree of the piezoelectric body 70 is preferably, for example, 80% or more. The (100) orientation degree of the protective layer 83 is preferably, for example, 30% or less. In addition, the protective layer 83 is formed such that its Young's modulus is lower than the Young's modulus of the piezoelectric body 70. The Young's modulus of the piezoelectric body 70 is, preferably, for example, approximately 150 GPa to 200 GPa. The Young's modulus of the protective layer 83 is preferably, for example, approximately 2 GPa to 10 GPa. In addition, the thickness of the protective layer 83 in the lamination direction is thinner than the thickness of the piezoelectric body 70 in the lamination direction. The protective film is preferably formed so that, for example, the thickness in the lamination direction is approximately 300 nanometers to 700 nanometers. In addition, the piezoelectric constant of the protective layer 83 is smaller than the piezoelectric constant of the piezoelectric body 70. A more detailed structure of the protective layer 83 will be described later.

As illustrated in FIG. 5, a wiring portion 85 is provided on the −X direction side rather than the end portion of the second electrode 80 in the −X direction. In FIG. 3, the wiring portion 85 is not illustrated. The wiring portion 85 is in the same layer as the second electrode 80, but is electrically discontinuous with the second electrode 80. The wiring portion 85 is formed from one end portion 70b of the piezoelectric body 70 in the −X direction to one end portion 60b of the first electrode 60 in the −X direction in a state where an interval is formed from the end portion 81b of the first layer 81. The one end portion 60b of the first electrode 60 in the −X direction is drawn out to the outside of one end portion 70b of the piezoelectric body 70. The wiring portion 85 is provided for each piezoelectric element 300, and a plurality of wiring portions 85 are disposed at predetermined intervals along the Y-axis direction. It is preferable that the wiring portion 85 is formed in the same layer as the second electrode 80. As a result, the cost can be reduced by simplifying a manufacturing step of the wiring portion 85. However, the wiring portion 85 may be formed in a layer different from the layer of the second electrode 80.

As illustrated in FIG. 5, the first drive wiring 91 is electrically coupled to the first electrode 60 which is an individual electrode, and the extension portions 92a and 92b of the second drive wiring 92 are electrically coupled to the second electrode 80 which is a common electrode. The first drive wiring 91 and the second drive wiring 92 function as drive wirings for applying a voltage for driving the piezoelectric body 70 from the wiring substrate 120.

The first drive wiring 91 is individually provided for each first electrode 60. As illustrated in FIG. 5, the first drive wiring 91 is coupled to the vicinity of the one end portion 60b of the first electrode 60 via the wiring portion 85, and is drawn out in the −X direction to reach a top of the vibration plate 50. The first drive wiring 91 is electrically coupled to the one end portion 60b of the first electrode 60 in the −X direction, which is drawn out to the outside of the one end portion 70b of the piezoelectric body 70. The wiring portion 85 may be omitted, and the first drive wiring 91 may be directly coupled to the one end portion 60b of the first electrode 60.

As illustrated in FIG. 3, the second drive wiring 92 extends along the Y-axis direction, bends at both ends in the Y-axis direction, and is drawn out along the X-axis direction. The second drive wiring 92 includes an extension portion 92a extending along the Y-axis direction and an extension portion 92b. As illustrated in FIG. 3 and FIG. 4, the end portions of the first drive wiring 91 and the second drive wiring 92 are extended so as to be exposed to the through hole 32 of the sealing substrate 30, and are electrically coupled to the wiring substrate 120 in the through hole 32.

The materials of the first drive wiring 91 and the second drive wiring 92 are conductive materials. For example, gold (Au), copper (Cu), titanium (Ti), tungsten (W), nickel (Ni), chromium (Cr), platinum (Pt), aluminum (Al), and the like can be used. In the present embodiment, gold (Au) is used for the first drive wiring 91 and the second drive wiring 92. In the present embodiment, the first drive wiring 91 and the second drive wiring 92 are formed by sputtering. The first drive wiring 91 and the second drive wiring 92 are not limited to the sputtering and may be formed by any known film forming technique.

The first drive wiring 91 and the second drive wiring 92 are formed in the same layer in a state of being electrically discontinuous with each other. As a result, the step of forming the first drive wiring 91 and the step of forming the second drive wiring 92 can be shared, and the manufacturing step can be simplified and the decrease in productivity of the liquid discharge head 510 can be suppressed as compared with the case where the first drive wiring 91 and the second drive wiring 92 are individually formed. Here, the first drive wiring 91 and the second drive wiring 92 may be formed in different layers from each other. The first drive wiring 91 and the second drive wiring 92 may have an adhesion layer that improves adhesion to the first electrode 60, the second electrode 80, or the vibration plate 50.

The wiring substrate 120 is configured with, for example, a flexible printed circuit (FPC). The wiring substrate 120 is formed with a plurality of wirings for coupled to the control section 580 and a power supply circuit (not illustrated). In addition, the wiring substrate 120 may be composed of any flexible substrate, such as Flexible Flat Cable (FFC), instead of FPC. An integrated circuit 121 including a switching element and the like is mounted at the wiring substrate 120. A command signal or the like for driving the piezoelectric element 300 is input to the integrated circuit 121. The integrated circuit 121 controls a timing at which a drive signal for driving the piezoelectric element 300 is supplied to the first electrode 60 based on the command signal.

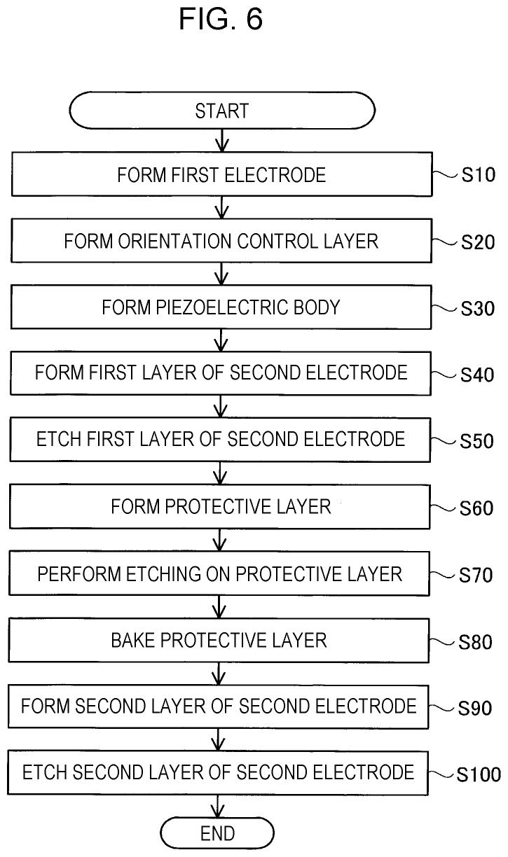

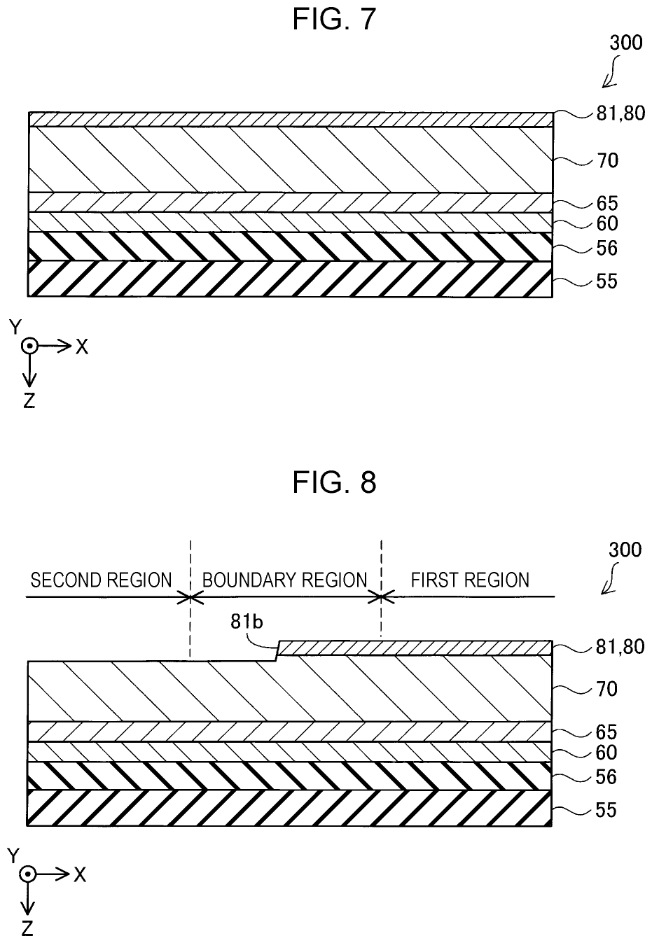

FIG. 6 is a flowchart illustrating a method of manufacturing the liquid discharge head 510. FIG. 6 illustrates a manufacturing step of the piezoelectric element 300 in a manufacturing step of the liquid discharge head 510. Hereinafter, the manufacturing step of the piezoelectric element 300 will be described with reference to FIGS. 6 to 12. FIGS. 7 to 12 are cross-sectional views illustrating the structure of the piezoelectric element 300 in each step of FIG. 6.

In step S10, the first electrode 60 is formed by sputtering on the −Z direction side of the insulator film 56 constituting the vibration plate 50. The first electrode 60 is not limited to sputtering, and may be formed by any known film forming technique.

In step S20, an orientation control layer 65 is formed on the −Z direction side of the first electrode 60. The orientation control layer 65 has a function of controlling the orientation of the piezoelectric body 70. The orientation control layer 65 is formed by, for example, applying a solution containing lead (Pb), bismuth (Bi), iron (Fe), and titanium (Ti) on the first electrode 60 by a spin coating method, and then drying, degreasing, and firing.

In step S30, the piezoelectric body 70 is formed on the −Z direction side of the orientation control layer 65. The piezoelectric body 70 is formed by, for example, applying a solution containing lead (Pb), zirconium (Zr), and titanium (Ti) on the orientation control layer 65 by a spin coating method, and then drying, degreasing, and firing. By repeating such a process a plurality of times, the piezoelectric body 70 having a predetermined thickness is formed.

In step S40, the first layer 81 of the second electrode 80 is formed on the −Z direction side of the piezoelectric body 70 by sputtering. The first layer 81 is not limited to sputtering, and may be formed by any known film forming technique. The step S40 is also referred to as a first step. FIG. 7 illustrates a state in which the first layer 81 is formed on the −Z direction side of the piezoelectric body 70.

In step S50, the first layer 81 of the second electrode 80 is etched by ion milling. FIG. 8 illustrates a state in which the first layer 81 is etched. In the present specification, as illustrated in FIG. 8, a region in which the piezoelectric body 70 and the second electrode 80 overlap in the Z-axis direction, which is the lamination direction, is referred to as a first region, a region in which the piezoelectric body 70 is present and the second electrode 80 is not present in the lamination direction is referred to as a second region, and a region that is a boundary between the first region and the second region in the X-axis direction, which is the extending direction, is referred to as a boundary region. In step S50, a part of the first layer 81 in the second region and the first layer 81 in the boundary region is removed by etching such that the end portion 81b of the first layer 81 in the −X direction is located in the boundary region. At this time, by performing over-etching, a part in the second region and the boundary region, that is, the surface of the piezoelectric body 70 on the −Z direction side is removed. As a result, the thickness of the piezoelectric body 70 in the second region in the lamination direction is thinner than the thickness of the piezoelectric body 70 in the first region in the lamination direction. The step S50 is also referred to as a second step. The first layer 81 may be etched by any known technique other than ion milling.

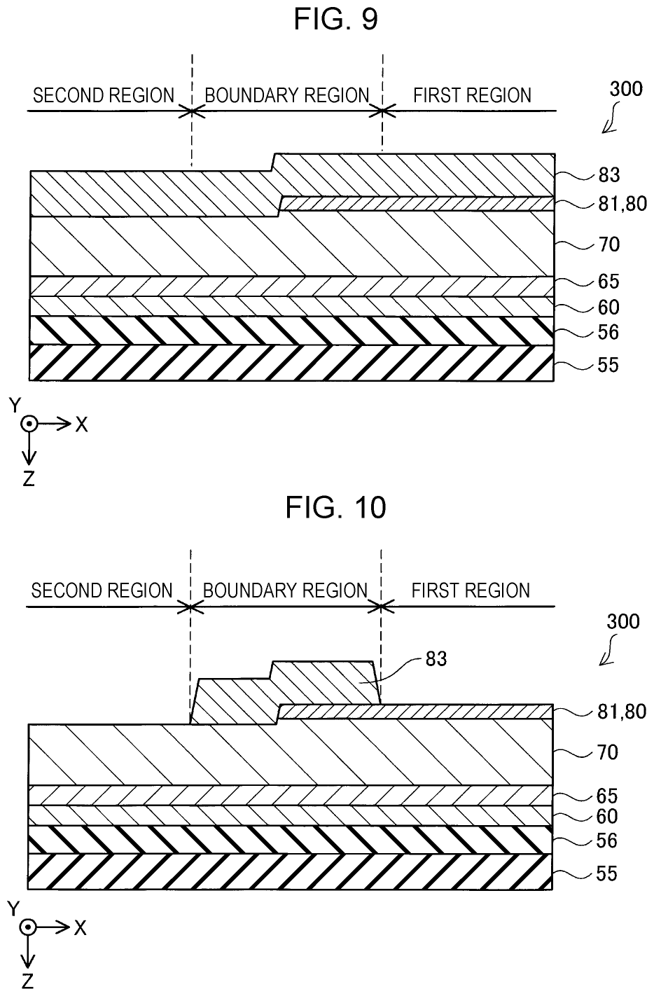

In step S60, the protective layer 83 is formed on the −Z direction side of the piezoelectric body 70 and the first layer 81. The protective layer 83 is formed by, for example, applying a solution containing Pb, Zr, and Ti on the piezoelectric body 70 by a spin coating method, and then drying, degreasing, and firing. In step S60, the protective layer 83 is preliminarily fired at a temperature of approximately 200° C. Step S60 is also referred to as a third step. FIG. 9 illustrates a state in which the protective layer 83 is formed on the −Z direction side of the piezoelectric body 70 and the first layer 81. As illustrated in FIG. 9, the protective layer 83 is formed so that the thickness in the lamination direction is uniform regardless of the location.

In step S70, the protective layer 83 is etched by wet etching, and the protective layer 83 in the first region and the second region is removed. The step S70 is also referred to as a fourth step. FIG. 10 illustrates a state in which the protective layer 83 in the first region and the second region is removed.

In step S80, the protective layer 83 is fired at a temperature of approximately 750° C.

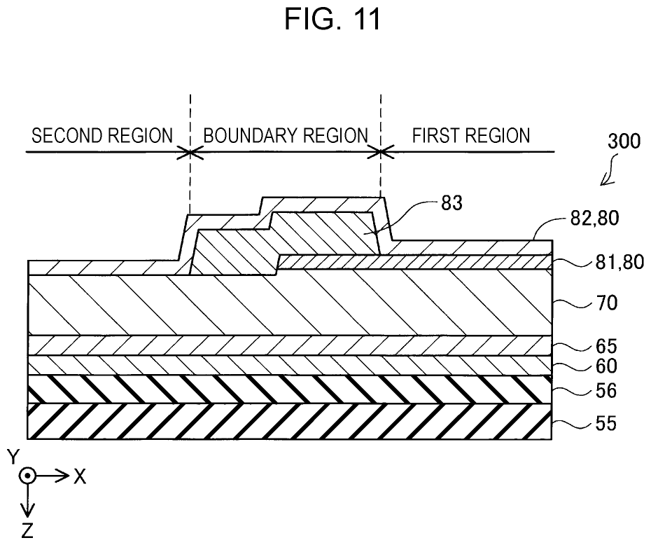

In step S90, the second layer 82 of the second electrode 80 is formed by sputtering on the −Z direction side of the piezoelectric body 70, the first layer 81, and the protective layer 83. The second layer 82 may be formed by any known film forming technique other than sputtering. FIG. 11 illustrates a state in which the second layer 82 is formed on the −Z direction side of the piezoelectric body 70, the first layer 81, and the protective layer 83.

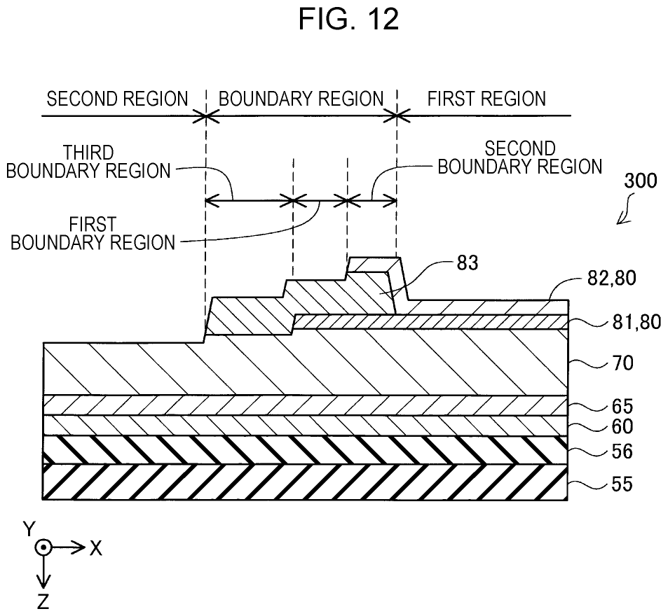

In step S100, the second layer 82 of the second electrode 80 is etched by ion milling. FIG. 12 illustrates a state in which the second layer 82 is etched. As illustrated in FIG. 12, the boundary region includes a first boundary region, a second boundary region, and a third boundary region. The second boundary region is a region closer to the first region in the X-axis direction, which is the extending direction, than the first boundary region. The third boundary region is a region closer to the second region than the first boundary region in the extending direction. In step S100, the second layer 82 in the second region, the first boundary region, and the third boundary region is removed by etching. At this time, by performing over-etching, the surface of the piezoelectric body 70 on the −Z direction side in the second region and the surface of the protective layer 83 on the −Z direction side in the first boundary region and the third boundary region are removed. The second layer 82 may be etched by any known technique other than ion milling.

By performing etching as described above, the first boundary region becomes a region in which the first layer 81 is present and the second layer 82 is not present in the lamination direction. The second boundary region is a region in which the first layer 81 and the second layer 82 are present in the lamination direction. The third boundary region is a region in which neither the first layer 81 nor the second layer 82 is present in the lamination direction. In addition, the thickness of the piezoelectric body 70 in the second region in the lamination direction is thinner than the thickness of the piezoelectric body 70 in the third boundary region in the lamination direction. The thickness of the piezoelectric body 70 in the third boundary region in the lamination direction is thinner than the thickness of the piezoelectric body 70 in the first boundary region, the second boundary region, and the first region in the lamination direction. In addition, the surface of the protective layer 83 in the third boundary region on the +Z direction side, that is, the surface on one side is located on the +Z direction side rather than the surface of the protective layer 83 on the +Z direction side in the first boundary region and the second boundary region. The surface of the protective layer 83 on the −Z direction side in the third boundary region, that is, the surface on the other side is located on the +Z direction side of the surface of the protective layer 83 rather than the surface on the −Z direction side in the first boundary region. The surface of the protective layer 83 on the −Z direction side in the third boundary region is located on the +Z direction side rather than the surface of the protective layer 83 on the −Z direction side in the second boundary region. The surface of the protective layer 83 on the −Z direction side in the first boundary region is located on the +Z direction side rather than the surface of the protective layer 83 on the −Z direction side in the second boundary region. As described above, the piezoelectric element 300 is manufactured.

When the first layer 81 in the second region and a part of the first layer 81 in the boundary region are removed by etching and a minute crack occurs in the piezoelectric body 70 in the vicinity of the end portion 81b of the first layer 81, the crack may become larger as the piezoelectric element 300 is driven. When moisture is mixed from the outside into the crack, the first electrode 60 and the second electrode 80 are short-circuited, and the burning occurs in the piezoelectric body 70. According to the liquid discharge head 510 in the first embodiment, in the boundary region where the end portion 81b of the first layer 81 is located in the extending direction, the protective layer 83 made of the same material as the piezoelectric body 70 is formed on the −Z direction side, which is the other side in the lamination direction with respect to the piezoelectric body 70. Therefore, it is possible to reduce the possibility that moisture is mixed into the crack generated in the piezoelectric body 70 in the vicinity of the end portion 81b of the first layer 81. In addition, compared to a case where the protective layer 83 is made of an organic material, it is possible to further reduce the possibility that moisture is mixed into the crack. As a result, it is possible to reduce the possibility that the burning occurs in the piezoelectric body 70 in the vicinity of the end portion of the second electrode 80.

A case where a crack occurs in the piezoelectric body 70 in the vicinity of the end portion 81b of the first layer 81 on the −X direction side when the first layer 81 is etched in step S50 of the manufacturing step of the piezoelectric body 70 will be described. In this case, the solution for forming the protective layer 83 is applied on the piezoelectric body 70 in step S60, and thus the solution enters the crack generated in the piezoelectric body 70. Then, by firing the protective layer 83 in step S80, the crack can be filled. Since the protective layer 83 is made of the same material as the piezoelectric body 70, the crack generated in the piezoelectric body 70 in the vicinity of the end portion 81b of the first layer 81 can be filled with the same material as the piezoelectric body 70. As a result, it is possible to reduce the possibility that the burning occurs in the piezoelectric body 70 in the vicinity of the end portion of the second electrode 80.

When the second layer 82 in the second region, the first boundary region, and the third boundary region is removed by etching, the crack may occur in the second region of the piezoelectric body 70, and the first boundary region and the third boundary region of the protective layer 83. However, since the second region of the piezoelectric body 70 is a non-active portion, even when the crack occurs, the possibility that the first electrode 60 and the second electrode 80 are short-circuited is low. In addition, since the protective layer 83 is formed on the −Z direction side of the piezoelectric body 70 and the first layer 81, even when a crack occurs, the possibility that the first electrode 60 and the second electrode 80 are short-circuited is low.

Further, in the present embodiment, since the orientation control layer 65 is formed between the first electrode 60 and the piezoelectric body 70, the (100) orientation degree of the piezoelectric body 70 can be increased. Since the orientation control layer 65 is not formed between the protective layer 83 and the piezoelectric body 70 and between the protective layer 83 and the first layer 81, the (100) orientation degree of the protective layer 83 is not as high as the (100) orientation degree of the piezoelectric body 70. Therefore, the piezoelectric body 70 can be more easily displaced in the lamination direction than the protective layer 83.

In the present embodiment, the Young's modulus of the piezoelectric body 70 is lower than the Young's modulus of the protective layer 83. Therefore, when a voltage is applied between the first electrode 60 and the second electrode 80, the piezoelectric body 70 can be displaced more greatly in the lamination direction than the protective layer 83.

In the present embodiment, the thickness of the protective layer 83 in the lamination direction is thinner than the thickness of the piezoelectric body 70 in the lamination direction. Therefore, when a voltage is applied between the first electrode 60 and the second electrode 80, the piezoelectric body 70 can be displaced more greatly in the lamination direction than the protective layer 83.

In the present embodiment, the piezoelectric constant of the protective layer 83 is smaller than the piezoelectric constant of the piezoelectric body 70. Therefore, when a voltage is applied between the first electrode 60 and the second electrode 80, the piezoelectric body 70 can be displaced more greatly in the lamination direction than the protective layer 83.

In the present embodiment, the second electrode 80 has a first layer 81 and a second layer 82 provided on the other side of the first layer 81. The protective layer 83 is formed after the first layer 81 is formed. Therefore, when the protective layer 83 is fired, the first layer 81 is also fired. In the first layer 81, the crystals are rearranged by firing and the first layer 81 tends to shrink in a direction intersecting the lamination direction. As a result, the piezoelectric element 300 and the vibration plate 50 bend in the +Z direction, the amount of displacement of the piezoelectric element 300 and the vibration plate 50 to the +Z direction side when the piezoelectric element 300 is driven is reduced, and the ink discharge characteristics from the nozzle 21 are deteriorated. In the present embodiment, since the second layer 82 is formed after the protective layer 83 is formed, the second layer 82 is not fired and does not shrink in the direction intersecting the lamination direction. As described above, in the present embodiment, it is possible to suppress the shrinkage of the entire second electrode 80 as compared with a case where the second electrode 80 has only the first layer 81. Therefore, the deterioration of the discharge characteristics of the ink from the nozzle 21 can be suppressed.

In the present embodiment, at least a part of the protective layer 83 is interposed between the first layer 81 and the second layer 82 in the lamination direction. Therefore, the end portion 81b of the first layer 81 in the extending direction can be covered with the protective layer 83.

In the present embodiment, the thickness of the piezoelectric body 70 in the third boundary region in the lamination direction is thinner than the thickness of the piezoelectric body 70 in the first boundary region and the second boundary region in the lamination direction. In other words, in the first layer 81 formed on the −Z direction side of the piezoelectric body 70, the first layer 81 in the first boundary region and the second boundary region is not removed by etching, and the first layer 81 of the third boundary region is all removed. Therefore, it is possible to reduce the possibility that the first layer 81 is short-circuited in the third boundary region.

In the present embodiment, the surface of the protective layer 83 on the +Z direction side in the third boundary region is located on the +Z direction side rather than the surface of the protective layer 83 on the +Z direction side in the first boundary region and the second boundary region. In other words, in the first layer 81 formed on the −Z direction side of the piezoelectric body 70, the first layer 81 in the first boundary region and the second boundary region is not removed by etching, and the first layer 81 of the third boundary region is all removed. Therefore, it is possible to reduce the possibility that the first layer 81 is short-circuited in the third boundary region.

In the present embodiment, the surface of the protective layer 83 on the −Z direction side in the first boundary region is located on the +Z direction side rather than the surface of the protective layer 83 on the −Z direction side in the second boundary region. In other words, in the second layer 82 formed on the −Z direction side of the protective layer 83, the second layer 82 in the second boundary region is not removed by etching, and the second layer 82 in the first boundary region is completely removed. Therefore, it is possible to reduce the possibility that the second layer 82 is short-circuited in the first boundary region.

In the present embodiment, the thickness of the piezoelectric body 70 in the second region in the lamination direction is thinner than the thickness of the piezoelectric body 70 in the second boundary region in the lamination direction. In other words, in the second layer 82 formed on the −Z direction side of the protective layer 83, the second layer 82 in the second boundary region is not removed by etching, and the second layer 82 in the second region is all removed. Therefore, it is possible to reduce the possibility that the second layer 82 is short-circuited in the second region.

In the present embodiment, the surface of the protective layer 83 on the −Z direction side in the third boundary region is located on the +Z direction side of the surface of the protective layer 83 on the −Z direction side in the first boundary region. In other words, in the first layer 81 formed on the −Z direction side of the piezoelectric body 70, the first layer 81 in the first boundary region is not removed by etching, and the first layer 81 of the third boundary region is entirely removed. Therefore, it is possible to reduce the possibility that the first layer 81 is short-circuited in the third boundary region.

Further, the liquid discharge device 500 of the present embodiment includes the liquid discharge head 510 and the control section 580 that controls the discharge operation of discharging the liquid from the liquid discharge head 510. Therefore, in the liquid discharge device 500, it is possible to reduce the possibility that the burning occurs in the piezoelectric body 70 in the vicinity of the end portion of the second electrode 80 included in the liquid discharge head 510.

### B. Other Embodiments

(B-1) In the above embodiment, the protective layer 83 is formed such that the (100) orientation degree thereof is lower than the (100) orientation degree of the piezoelectric body 70. On the other hand, the protective layer 83 may be formed such that the (100) orientation degree thereof is higher than the (100) orientation degree of the piezoelectric body 70.

(B-2) In the above embodiment, the protective layer 83 is formed such that the Young's modulus thereof is higher than the Young's modulus of the piezoelectric body 70. On the other hand, the protective layer 83 may be formed such that the Young's modulus thereof is lower than the Young's modulus of the piezoelectric body 70.

(B-3) In the above embodiment, the thickness of the protective layer 83 in the lamination direction is thinner than the thickness of the piezoelectric body 70 in the lamination direction. On the other hand, the thickness of the protective layer 83 in the lamination direction may be thicker than the thickness of the piezoelectric body 70 in the lamination direction.

(B-4) In the above embodiment, the protective layer 83 is formed such that the piezoelectric constant thereof is smaller than the piezoelectric constant of the piezoelectric body 70. On the other hand, the protective layer 83 may be formed such that the piezoelectric constant thereof is larger than the piezoelectric constant of the piezoelectric body 70.

(B-5) In the above embodiment, the protective layer 83 has the first layer 81 and the second layer 82. On the other hand, the protective layer 83 may not have the second layer 82.

(B-6) In the above embodiment, at least a part of the protective layer 83 is interposed between the first layer 81 and the second layer 82 in the lamination direction. On the other hand, the protective layer 83 may not be interposed between the first layer 81 and the second layer 82 in the lamination direction.

(B-7) In the above embodiment, the thickness of the piezoelectric body 70 in the third boundary region in the lamination direction is thinner than the thickness of the piezoelectric body 70 in the first boundary region and the second boundary region in the lamination direction. On the other hand, the thickness of the piezoelectric body 70 in the third boundary region in the lamination direction may be the same as the thickness of the piezoelectric body 70 in the first boundary region and the second boundary region in the lamination direction. That is, when the first layer 81 in the second region and a part of the first layer 81 in the boundary region are removed by etching, the piezoelectric body 70 in the boundary region may not be over-etched.

(B-8) In the above embodiment, the surface of the protective layer 83 in the third boundary region on the +Z direction side is located on the +Z direction side of the surface of the protective layer 83 on the +Z direction side in the first boundary region. On the other hand, the surface of the protective layer 83 on the +Z direction side in the third boundary region and the surface of the protective layer 83 on the +Z direction side in the first boundary region may be located at the same position in the lamination direction.

(B-9) In the above embodiment, the surface of the protective layer 83 on the −Z direction side in the third boundary region is located on the +Z direction side of the surface of the protective layer 83 on the −Z direction side in the second boundary region. On the other hand, the surface of the protective layer 83 on the −Z direction side in the third boundary region and the surface of the protective layer 83 on the −Z direction side in the second boundary region may be located at the same position in the lamination direction. That is, when the second layer 82 in the second region, the first boundary region, and the third boundary region is removed by etching, the protective layer 83 of the third boundary region may not be over-etched.

(B-10) In the above embodiment, the surface of the protective layer 83 on the −Z direction side in the first boundary region is located on the +Z direction side of the surface of the protective layer 83 on the −Z direction side in the second boundary region. On the other hand, the surface of the protective layer 83 on the −Z direction side in the first boundary region and the surface of the protective layer 83 on the −Z direction side in the second boundary region may be located at the same position in the lamination direction. That is, when the second layer 82 in the second region, the first boundary region, and the third boundary region is removed by etching, the protective layer 83 in the first boundary region may not be over-etched.

(B-11) In the above embodiment, the thickness of the piezoelectric body 70 in the second region in the lamination direction is thinner than the thickness of the piezoelectric body 70 in the second boundary region in the lamination direction. On the other hand, the thickness of the piezoelectric body 70 in the second region in the lamination direction may be the same as the thickness of the piezoelectric body 70 in the second boundary region in the lamination direction. That is, when the first layer 81 in the second region and a part of the first layer 81 in the boundary region are removed by etching, the piezoelectric body 70 in the second region may not be over-etched. In addition, when the second layer 82 in the second region, the first boundary region, and the third boundary region is removed by etching, the piezoelectric body 70 in the second region may not be over-etched.

(B-12) In the above embodiment, the surface of the protective layer 83 on the −Z direction side in the third boundary region is located on the +Z direction side of the surface of the protective layer 83 on the −Z direction side in the first boundary region. On the other hand, the surface of the protective layer 83 on the −Z direction side in the third boundary region and the surface of the protective layer 83 on the −Z direction side in the first boundary region may be located at the same position in the lamination direction.

(B-13) In the above embodiment, the protective layer 83 is made of the same material as the piezoelectric body 70. On the other hand, the protective layer 83 may contain the same material as the piezoelectric body 70.

### C. Other Aspects

The present disclosure is not limited to the above-described embodiments, and can be realized in various aspects without departing from the gist thereof. For example, the present disclosure can also be realized in the following aspects. Technical features in the embodiments corresponding to technical features in respective aspects described below can be appropriately replaced or combined in order to solve some or all of the problems of the present disclosure, or achieve some or all of the effects of the present disclosure. Further, when the technical features are not described as essential in the present specification, the technical features can be appropriately deleted.

(1) According to a first aspect of the present disclosure, there is provided a liquid discharge head. The liquid discharge head includes a piezoelectric body, a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven, a first electrode provided on one side of a lamination direction, which is a direction intersecting the extending direction and the arrangement direction, with respect to the piezoelectric body, a second electrode provided on another side of the lamination direction, which is a side opposite to the one side, with respect to the piezoelectric body, and a protective layer provided on the other side with respect to the piezoelectric body in a boundary region, which is a boundary between a first region and a second region, in the extending direction when the first region is set to a region where the piezoelectric body overlaps the second electrode in the lamination direction, and the second region is set to a region where the piezoelectric body is present and the second electrode is not present in the lamination direction, in which the protective layer is made of the same material as the piezoelectric body.

According to such an aspect, when the second electrode in the second region is removed by etching and even when a crack is generated in the piezoelectric body in the vicinity of the end portion of the second electrode, it is possible to reduce the possibility that moisture is mixed into the crack. As a result, it is possible to reduce the possibility that the burning occurs in the piezoelectric body in the vicinity of the end portion of the second electrode.

(2) In the above-described aspect, the piezoelectric body and the protective layer may contain lead zirconate titanate.

(3) In the above-described aspect, a (100) orientation degree of the protective layer may be lower than a (100) orientation degree of the piezoelectric body.

According to the aspect, the piezoelectric body can be more easily displaced in the lamination direction than the protective layer.

(4) In the above-described aspect, a Young's modulus of the protective layer may be higher than a Young's modulus of the piezoelectric body.

According to the aspect, when a voltage is applied between the first electrode and the second electrode, the piezoelectric body can be displaced in the lamination direction more than the protective layer.

(5) In the above-described aspect, a thickness of the protective layer in the lamination direction may be thinner than a thickness of the piezoelectric body in the lamination direction.

According to the aspect, when a voltage is applied between the first electrode and the second electrode, the piezoelectric body can be displaced in the lamination direction more than the protective layer.

(6) In the above-described aspect, a piezoelectric constant of the protective layer may be smaller than a piezoelectric constant of the piezoelectric body.

According to the aspect, when a voltage is applied between the first electrode and the second electrode, the piezoelectric body can be displaced in the lamination direction more than the protective layer.

(7) In the above-described aspect, the boundary region may include a first boundary region, a second boundary region that is closer to the first region than the first boundary region in the extending direction, and a third boundary region that is closer to the second region than the first boundary region in the extending direction.

(8) In the above-described aspect, the second electrode may include a first layer and a second layer provided on the other side of the first layer.

According to such an aspect, it is possible to suppress the shrinkage of the entire second electrode when the protective layer is fired as compared with a case where the second electrode has only the first layer.

(9) In the above-described aspect, at least a part of the protective layer may be interposed between the first layer and the second layer in the lamination direction.

According to the aspect, the end portion of the first layer in the extending direction can be covered with the protective layer.

(10) In the above-described aspect, in the first boundary region, the first layer may be present and the second layer may not be present in the lamination direction, in the second boundary region, the first layer and the second layer may be present in the lamination direction, and in the third boundary region, neither the first layer nor the second layer may be present in the lamination direction.

(11) In the above-described aspect, a thickness of the piezoelectric body in the lamination direction in the third boundary region may be thinner than a thickness of the piezoelectric body in the lamination direction in the first boundary region and the second boundary region.

According to such an aspect, it is possible to reduce the possibility that the first layer is short-circuited in the third boundary region.

(12) In the above-described aspect, a surface of the protective layer on the one side in the third boundary region may be located on the one side rather than surfaces of the protective layer on the one side in the first boundary region and the second boundary region.

According to such an aspect, it is possible to reduce the possibility that the first layer is short-circuited in the third boundary region.

(13) In the above-described aspect, a surface of the protective layer on the other side in the third boundary region may be located on the one side rather than a surface of the protective layer on the other side in the second boundary region.

(14) In the above-described aspect, a surface of the protective layer on the other side in the first boundary region may be located on the one side rather than a surface of the protective layer on the other side in the second boundary region.

According to such an aspect, it is possible to reduce the possibility that the second layer is short-circuited in the first boundary region.

(15) In the above-described aspect, a thickness of the piezoelectric body in the lamination direction in the second region may be thinner than a thickness of the piezoelectric body in the lamination direction in the second boundary region.

According to such an aspect, it is possible to reduce the possibility that the second layer is short-circuited in the second region.

(16) In the above-described aspect, a surface of the protective layer on the other side in the third boundary region may be located on the one side rather than a surface of the protective layer on the other side in the first boundary region.

According to such an aspect, it is possible to reduce the possibility that the first layer is short-circuited in the third boundary region.

(17) According to a second aspect of the present disclosure, there is provided a liquid discharge device. The liquid discharge device includes the liquid discharge head according to the first aspect, and a control section that controls a discharge operation of discharging a liquid from the liquid discharge head.

According to the aspect, in the liquid discharge device, it is possible to reduce the possibility that the burning occurs in the piezoelectric body in the vicinity of the end portion of the second electrode included in the liquid discharge head.

(18) According to a third aspect of the present disclosure, there is provided a method of manufacturing a liquid discharge head. The method of manufacturing a liquid discharge head, the liquid discharge head including a piezoelectric body and a first electrode provided on one side of a lamination direction with respect to the piezoelectric body, the method includes a first step of forming a second electrode on another side of the lamination direction, which is a side opposite to the one side, with respect to the piezoelectric body; a second step of removing the second electrode in a second region by etching such that an end portion of the second electrode in an extending direction, which is a direction intersecting the lamination direction, is located at a boundary region when a region where the piezoelectric body overlaps the second electrode in the lamination direction is set to a first region, a region where the piezoelectric body is present and the second electrode is not present in the lamination direction is set to the second region, and a region which is a boundary between the first region and the second region in the extending direction is set to the boundary region; a third step of forming a protective layer made of the same material as the piezoelectric body on the other side of the piezoelectric body and the second electrode; and a fourth step of removing the protective layer in the first region and the second region by etching.

According to such an aspect, when the second electrode in the second region is removed by etching and even when a crack is generated in the piezoelectric body in the vicinity of the end portion of the second electrode, it is possible to fill the crack generated in the piezoelectric body in the step of forming the protective layer. Therefore, it is possible to reduce the possibility that the burning occurs in the piezoelectric body in the vicinity of the end portion of the second electrode.

The present disclosure can also be realized in various aspects other than the liquid discharge device and the liquid discharge head. For example, it is possible to realize the present disclosure with an aspect of a method for manufacturing a liquid discharge head, a method for manufacturing a liquid discharge device, or the like.

The present disclosure is not limited to the ink jet method, and can be applied to any liquid discharge device that discharges a liquid other than the ink and a liquid discharge head that is used for the liquid discharge device. For example, the present disclosure can be applied to the following various liquid discharge devices and liquid discharge heads thereof.

(1) An image recording device such as a facsimile device.

(2) A color material discharge device used for manufacturing a color filter for an image display device such as a liquid crystal display.

(3) An electrode material discharge device used for forming electrodes of an organic Electro Luminescence (EL) display, a Field Emission Display (FED), or the like.

(4) A liquid discharge device that discharges a liquid containing a bioorganic material used for manufacturing a biochip.

(5) A sample discharge device as a precision pipette.

(6) A lubricating oil discharge device.

(7) A resin liquid discharge device.

(8) A liquid discharge device that discharges lubricating oil with pinpoint to a precision machine such as a watch or a camera.

(9) A liquid discharge device that discharges a transparent resin liquid, such as an ultraviolet curable resin liquid, onto a substrate in order to form a micro hemispherical lens (optical lens) or the like used for an optical communication element or the like.

(10) A liquid discharge device that discharges an acidic or alkaline etching liquid for etching a substrate or the like.

(11) A liquid discharge device including a liquid consumption head that discharges any other minute amount of droplets.

Further, the “liquid” may be any material that can be consumed by the liquid discharge device. For example, the “liquid” may be a material in a state when a substance is liquefied, and the “liquid” includes a liquid state material with high or low viscosity and a liquid state material, such as a sol, gel water, other inorganic solvent, organic solvent, solution, liquid resin, and liquid metal (metal melt). Further, the “liquid” includes not only a liquid as a state of a substance but also a liquid in which particles of a functional material made of a solid substance, such as a pigment or a metal particle, are dissolved, dispersed, or mixed in a solvent. Further, the following is mentioned as a typical example of a liquid.

(1) Adhesive main agent and curing agent.

(2) Paint-based paints and diluents, clear paints and diluents.

(3) Main solvent and diluting solvent containing cells of ink for cells.

(4) Metallic leaf pigment dispersion liquid and diluting solvent of ink (metallic ink) that develops metallic luster.

(5) Gasoline/diesel and biofuel for vehicle fuel.

(6) Main ingredients and protective ingredients of medicine.

(7) Light Emitting Diode (LED) fluorescent material and encapsulant.

What is claimed is:

1. A liquid discharge head comprising:
a piezoelectric body;
a pressure chamber substrate provided with a plurality of pressure chambers arranged in an arrangement direction, which is a direction intersecting an extending direction of the pressure chamber, the pressure chamber being configured to apply pressure to a liquid stored inside when the piezoelectric body is driven;
a first electrode provided on one side of a lamination direction, which is a direction intersecting the extending direction and the arrangement direction, with respect to the piezoelectric body;
a second electrode provided on another side of the lamination direction, which is a side opposite to the one side, with respect to the piezoelectric body; and
a protective layer provided on the other side with respect to the piezoelectric body in a boundary region, which is a boundary between a first region and a second region, in the extending direction when the first region is set to a region where the piezoelectric body overlaps the second electrode in the lamination direction, and the second region is set to a region where the piezoelectric body is present and the second electrode is not present in the lamination direction, wherein
the protective layer is made of the same material as the piezoelectric body.

2. The liquid discharge head according to claim 1, wherein
the piezoelectric body and the protective layer contain lead zirconate titanate.

3. The liquid discharge head according to claim 1, wherein
a (100) orientation degree of the protective layer is lower than a (100) orientation degree of the piezoelectric body.

4. The liquid discharge head according to claim 1, wherein
a Young's modulus of the protective layer is higher than a Young's modulus of the piezoelectric body.

5. The liquid discharge head according to claim 1, wherein
a thickness of the protective layer in the lamination direction is thinner than a thickness of the piezoelectric body in the lamination direction.

6. The liquid discharge head according to claim 1, wherein
a piezoelectric constant of the protective layer is smaller than a piezoelectric constant of the piezoelectric body.

7. The liquid discharge head according to claim 1, wherein
the boundary region includes
a first boundary region,
a second boundary region that is closer to the first region than the first boundary region in the extending direction, and
a third boundary region that is closer to the second region than the first boundary region in the extending direction.

8. The liquid discharge head according to claim 7, wherein
the second electrode has
a first layer, and
a second layer provided on the other side of the first layer.

9. The liquid discharge head according to claim 8, wherein
at least a part of the protective layer is interposed between the first layer and the second layer in the lamination direction.

10. The liquid discharge head according to claim 8, wherein
in the first boundary region, the first layer is present and the second layer is not present in the lamination direction,
in the second boundary region, the first layer and the second layer are present in the lamination direction, and
in the third boundary region, neither the first layer nor the second layer is present in the lamination direction.

11. The liquid discharge head according to claim 8, wherein
a thickness of the piezoelectric body in the lamination direction in the third boundary region is thinner than a thickness of the piezoelectric body in the lamination direction in the first boundary region and the second boundary region.

12. The liquid discharge head according to claim 11, wherein
a surface of the protective layer on the one side in the third boundary region is located on the one side rather than surfaces of the protective layer on the one side in the first boundary region and the second boundary region.

13. The liquid discharge head according to claim 12, wherein
a surface of the protective layer on the other side in the third boundary region is located on the one side rather than a surface of the protective layer on the other side in the second boundary region.

14. The liquid discharge head according to claim 8, wherein
a surface of the protective layer on the other side in the first boundary region is located on the one side rather than a surface of the protective layer on the other side in the second boundary region.

15. The liquid discharge head according to claim 8, wherein
a thickness of the piezoelectric body in the lamination direction in the second region is thinner than a thickness of the piezoelectric body in the lamination direction in the second boundary region.

16. The liquid discharge head according to claim 14, wherein
a surface of the protective layer on the other side in the third boundary region is located on the one side rather than a surface of the protective layer on the other side in the first boundary region.

17. A liquid discharge device comprising:
the liquid discharge head according to claim 1; and
a control section that controls a discharge operation of discharging a liquid from the liquid discharge head.

18. A method of manufacturing a liquid discharge head, the liquid discharge head including a piezoelectric body and a first electrode provided on one side of a lamination direction with respect to the piezoelectric body, the method comprising:
a first step of forming a second electrode on another side of the lamination direction, which is a side opposite to the one side, with respect to the piezoelectric body;
a second step of removing the second electrode in a second region by etching such that an end portion of the second electrode in an extending direction, which is a direction intersecting the lamination direction, is located at a boundary region when a region where the piezoelectric body overlaps the second electrode in the lamination direction is set to a first region, a region where the piezoelectric body is present and the second electrode is not present in the lamination direction is set to the second region, and a region which is a boundary between the first region and the second region in the extending direction is set to the boundary region;
a third step of forming a protective layer made of the same material as the piezoelectric body on the other side of the piezoelectric body and the second electrode; and
a fourth step of removing the protective layer in the first region and the second region by etching.
